(19) United States
(12) Patent Application Publication
(10) Pub. No.: US 2021/0144872 A1
(43) Pub. Date: May 13, 2021

(54) HOUSING FOR AN ELECTRICAL DEVICE, HAVING A TIGHTLY FITTING HOUSING PART

(71) Applicant: Robert Bosch GmbH, Stuttgart (DE)

(72) Inventors: Bjoern Schenk, Stuttgart (DE); Joerg Moessner, Wannweil (DE)

(21) Appl. No.: 16/620,609

(22) PCT Filed: May 3, 2018
(86) PCT No.: PCT/EP2018/061266

§ 371 Date: Dec. 9, 2019

(30) Foreign Application Priority Data
Jun. 8, 2017 (DE) 10 2017 209 657.8

(51) Int. Cl. H05K 5/06; H02K 5/10; H05K 5/04; B29C 45/14; B29C 65/16; B29C 65/00

(52) U.S. Cl. CPC H05K 5/066; H02K 5/10; B29C 66/721; B29C 45/14311; B29C 65/16; H05K 5/04

(57) ABSTRACT

The invention relates to a housing for an electrical device, in particular an electrical machine. The housing encloses a cavity. The housing has a housing cup and a housing part. The housing part, which is formed, for example, by a closing element, in particular a housing cover, is designed to be connected to the housing cup, in particular separably or inseparably, or to close the housing cup. According to the invention, the housing cup, in particular a housing wall of the housing cup, has an opening. The housing cup is made of metal, in particular steel or aluminum, at least in the region of a housing cup edge extending peripherally around the opening. The housing part is preferably made of plastic. The housing preferably has an adapter, which is in particular tubular, for connecting the housing cup to the housing part. The adapter is injection-molded or fused onto a longitudinal section of the housing cup edge. The adapter has, at an end opposite the housing cup, an adapter edge, which surrounds an adapter opening, is in particular in the form of a flange and is designed to be adhesively bonded or welded, in particular tightly, to the housing part.

### BACKGROUND OF THE INVENTION

The invention relates to a housing for an electrical device, in particular an electrical machine. The housing encloses a cavity. The housing has a housing cup and a housing part. The housing part, which is formed, for example, by a closure element, in particular a housing cover, is formed to be in particular detachably or undetachably connected to the housing cup and to close off the housing cup.

### SUMMARY OF THE INVENTION

According to the invention, the housing cup, in particular a housing wall of the housing cup, has an opening. The housing cup at least in the region of a housing cup edge formed circumferentially around the opening is formed from metal, in particular steel or aluminum. The housing part is preferably formed from plastic. The housing preferably has an in particular tubular adapter for connection of the housing cup to the housing part. The adapter is molded or fused onto a longitudinal portion of the housing cup edge. The adapter has, at an end opposite the housing cup, an adapter edge surrounding an adapter opening which is in particular web-shaped, which adapter edge is formed to be in particular tightly glued or welded to the housing part. As a result of the adapter, a housing part which is formed to receive a control device or electrical components can thus advantageously be connected tightly to the housing cup, wherein the adapter has, for example, toward the housing part in the region of the adapter opening an in particular standardized interface for the housing part. The housing, in particular the housing cup, can thus furthermore advantageously be closed off in a media-impervious manner by means of the housing part so that no media such as water or oil can penetrate into the housing interior at a joint between the housing part and the housing cup.

As a result of the adapter, an adapter edge pointing toward the housing cup edge can have a curve which encloses the opening and which is thus adapted to the form of the housing edge, preferably by fusion casting of the adapter material. Irrespective of this or in addition to this, the adapter edge which points toward the housing part, in particular toward the closure element can have a curve which is adapted to the housing part.

In one preferred embodiment, the housing, in particular the housing wall, has at least one rounding. For example, the housing, preferably at least the housing cup, is formed to be cylindrical in one simple embodiment. The housing cup is further preferably formed by a cylindrical housing cup, in particular metal cup. The housing itself can thus be formed to be stable, in particular as a housing of an electric motor, wherein the housing part, for example, a housing cover for receiving a control device, is formed from plastic and can thus be provided with a low weight and at low cost.

In another embodiment, the housing and/or the housing edge is formed to be polygonal. The adapter can advantageously, by means of forming onto the housing edge, form a tight thread-free connection even with non-rotationally symmetrical housing edge forms.

In one preferred embodiment, the housing cup edge has toward the adapter a curve which spans the opening and which has at least one rounding and/or at least one corner.

The adapter is preferably formed corresponding to the housing cup edge, wherein the adapter edge forms a closed curve.

The adapter can thus advantageously adapt a device housing, formed by the housing part, for example, for a control device, to a plurality of metal housing cup forms and housing cup sizes. The closure element can advantageously also tightly close off the housing cup by means of the adapter since, without the adapter, the seal can otherwise form a weak point between the closure element and the housing.

In one preferred embodiment, the opening of the adapter to the housing part is preferably formed to be round toward the housing cover, in particular circular. The housing part can thus be easily placed in a tightly closing manner on the adapter opening and glued or welded with the adapter. For example, the adapter can adapt a housing part with a round opening to a square housing.

In one preferred embodiment, the longitudinal portion of the housing cup edge has clearances generated in particular by milling or recesses generated in particular by means of laser beams. The adapter, in particular the adapter material, preferably engages in a positive-locking manner in the clearances or recesses.

The clearances or recesses are preferably generated by means of laser beams. The adapter can thus be fixedly connected advantageously in a positive-locking manner and further advantageously tightly to the metal housing. Superstructures and undercuts protruding as a result of remelting processes can advantageously be generated in the housing edge.

The clearances or recesses are generated, for example, by means of material removal or material reshaping, in particular laser melting, cutting or milling, or chemical etching. The recesses can have, for example, a depth extent between 5 and 500 micrometers.

The structures generated by means of laser beams, in particular pulsed laser beams, comprising recesses or additionally elevations, have, for example, a depth in particular transverse to the surface of the housing edge between 150 and 500 micrometers. A structure is preferably generated by the laser beams, one combination of elevations and recesses arranged adjacent to one another and overlapping one another is formed so that a plurality of geometrical undercuts are thus formed as a result of this.

A method for generating the recesses is described, for example, in DE 10 2007 023 418 A1.

In one preferred embodiment, a pattern, in particular whirl pattern, is formed by the clearances or recesses in the plane of the housing edge. The whirl pattern preferably comprises a curve or several curves. To this end, for example, the laser or milling tool can, during penetration into the housing edge of the housing, move in particular in whirling circular movements in different directions within the longitudinal portion of the housing edge, wherein the housing is rotated along a longitudinal extent during remelting by the laser beam and/or the laser beam is moved around the housing edge. No preferred orientation can preferably be formed by means of the whirl pattern in the case of the curves of the whirl pattern formed by the recesses.

In one preferred embodiment of the housing, the adapter is connected in the region of the adapter edge to the housing part by means of a hot joining method, for example, infrared welding, hot gas welding, hot plate welding, ultrasound welding or laser welding, in particular laser radiation welding. As a result of this, the housing part is connected to the housing cup in particular non-detachably.

The adapter is preferably formed at least in the region of the adapter edge by a plastic which is formed to only absorb to a small extent or not to absorb laser beams, in particular infrared radiation, so that the adapter is formed to be translucent for the laser beams in the region of the adapter edge which forms a connection portion for connection to the housing cover. The laser beams can thus be transmitted through the adapter edge, strike the housing part and be absorbed there. The housing part, for example the housing cover, can thus melt with the adapter edge.

The laser beams for generating the structure, in particular recesses and/or clearances, are preferably pulsed laser beams, preferably with pulses in the range of nanoseconds, preferably between 20 and 50 nanoseconds. The wavelength of the laser beams is preferably between 1000 and 1200 nanometers, particularly preferably 1030 nanometers. The laser beams are preferably formed to melt and reshape the material of the housing. The structure can advantageously be a pattern formed in the plane of the housing edge. As a result of this, melt beads adjacent to the recesses can also be generated in the region of the recesses, which melt beads can be enclosed and thus embedded by the adapter material in order to form a positive locking. During shaping, in particular during injection molding or hot reshaping, the adapter material can advantageously penetrate into the undercuts of the surface structure of the housing edge and thus generate an in particular multi-dimensional positive locking and thus generate a fixed connection between the adapter and the housing edge. Imperviousness is thus achieved between the adapter and the housing edge via a labyrinth formed by the surface structure by virtue of the fact that a leakage path for media is formed to be sufficiently long as a result of numerous deflections at the undercuts in the contact region between the adapter and the housing edge.

A circumferential projection region, in particular ring, web or bead, is preferably formed on the housing part. The projection region is formed to absorb laser beams, in particular infrared radiation, and thereby perform melting. The housing cover can thus be pressed with oversize into the adapter opening. The projection region can then be melted from the outside by an in particular radially inwardly directed laser beam and thus connected to the adapter. The connection to the adapter is, for example, a firmly bonded or an adhesive connection. During melting of the projection region, the compressive tension as a result of melting expulsion can be reduced. The compressive tension thus advantageously serves as a supporting joining force during the welding process.

In one preferred embodiment, the adapter is formed from a thermoplastic. The thermoplastic is, for example, PET (PET=polyethylene terephthalate), PBT (PBT=poly butylene terephthalate), PPS (poly(propylene sulfide)), or polyamide.

In one preferred variant, the adapter is formed from different plastics, wherein the adapter edge is formed from a plastic formed for laser radiation welding and a holding portion of the adapter connected to the housing edge is formed from a fiber-reinforced plastic. The fibers are, for example, glass fibers. The glass fibers are preferably formed to be short in such a manner that they can penetrate into the above-mentioned recesses at least with one longitudinal portion or entirely.

The adapter and the housing part are preferably formed from the same plastic material, for example, a thermoplastic. The adapter edge or the housing part can be formed from laser-transparent plastic. The adapter edge is preferably formed for joining with the housing part, wherein the adapter edge forms a joint. An opening edge of the adapter edge preferably forms a closed line, wherein an opening of the housing part is correspondingly shaped so that the housing part and the adapter tightly adjoin one another in the region of the adapter edge.

The electrical device is preferably an electrical machine. The housing part is preferably formed to receive a control device for the electrical machine or electrical components of the electrical device.

The invention also relates to a method for connection of a housing part, in particular a housing cover to a housing cup. In the case of the method, clearances are generated in a housing wall of the housing cup by means of laser beams. In a further step, a plastic adapter is molded onto the housing, in particular a housing cup edge of the housing cup, wherein the plastic penetrates into the clearances and/or the undercuts and thus connects the adapter to the housing cup in a fixed and impervious manner. An adapter edge which encloses the adapter opening is formed on the adapter. In a further step, the adapter edge is connected to the housing part, for example, as described on the basis of the example of welding, and the housing is thus closed off in particular in a fluid-impervious and/or gas-impervious manner. The electric machine, in particular the electric motor and/or generator, is thus sealed off with respect to a fluid, in particular media such as oil or water.

In the case of the method, recesses, undercuts or additionally projections, in particular beads, are preferably generated, in particular before molding of the adapter onto the housing cup, by means of laser beams in the housing wall by material remelting so that the adapter can be connected to the housing in a positive-locking manner during molding on the housing edge. The adapter is thus advantageously connected to the housing in a rotationally fixed and/or tensile-strengthened manner. Thermal expansions of the housing, in particular caused by different coefficients of expansion of the adapter and the housing wall, can thus advantageously also not detach the adapter from the housing edge.

In one preferred embodiment, the housing part or the housing cover and the adapter edge of the adapter are welded to one another by means of laser beams.

As a result, the housing part or the housing cover is connected to the adapter in a fluid-impervious and/or gas-impervious manner. The housing part, in particular the housing cover, and the adapter preferably have the same thermal coefficient of expansion. The weld point between the housing part and the adapter can also advantageously not rip open in case of thermal loading so that the housing part is connected to the adapter in a firmly bonded and tear-resistant, and thus impervious manner.

### BRIEF DESCRIPTION OF THE DRAWINGS

The invention will now be described below on the basis of figures and further exemplary embodiments. Further advantageous embodiment variants will become apparent from a combination of the features described in the figures and/or in the dependent claims.

FIG. 1 shows an exemplary embodiment for an electrical device in the case of which a housing cup is connected to a housing cover by means of an adapter molded onto the housing cup.

FIG. 2 shows recesses and undercuts generated by means of laser beams in a housing edge.

### DETAILED DESCRIPTION

FIG. 1 shows—schematically—an exemplary embodiment of an electrical device 1, in this exemplary embodiment, an electrical machine, in particular a generator or an electric motor. Device 1 has a housing 2 which, in this exemplary embodiment, has a housing cup 27. Housing 2 encloses a cavity 3. In this exemplary embodiment, the electric motor, of which a stator 15 and a rotor 16 are represented, is received in cavity 3. A rotor shaft 17 of rotor 16 extends along a longitudinal axis 18 of electrical device 1.

Housing cup 27, which, in this exemplary embodiment, is formed by a metal housing cup, in particular aluminum housing cup, has a housing cup edge 4 which encloses an opening 10 toward cavity 3. Housing 2 also has a housing part 9 which forms a housing cover and is formed to receive electrical components of device 1.

In this exemplary embodiment, a separating wall 5 which extends transversely and thus radially inward is molded onto a housing wall of housing cup 27. Separating wall 5 separates cavity 3 in which the electric motor is received from a cavity 29 which is enclosed by housing part 9. In this exemplary embodiment, housing part 9 also forms a closure element which is formed to close opening 10. In this exemplary embodiment, a control device 22 is received as an electrical component of device 1 in cavity 29. Control device 22 is held by a web 24 which is molded onto housing part 9. Control device 22 has, in this exemplary embodiment, a rotor position sensor 25 which is arranged in the active region of an end portion 26 of rotor shaft 17. Rotor position sensor 25 is, for example, a Hall sensor, a GMR sensor (GMR=Giant-Magneto-Resistive) or an AMR sensor (AMR=Anisotrope-Magneto-Resistive). End portion 26 has, for example, a permanent magnet so that rotor position sensor 25 can detect a rotor position of rotor 16 and can generate a corresponding rotor position signal in order to actuate stator 15 by means of control device 22.

Housing 2 also has an adapter 6. Housing part 9, which, in this exemplary embodiment, is formed by a plastic housing part, is connected by means of adapter 6 to housing cup 27.

In this exemplary embodiment, adapter 6 is formed by an adapter ring which is molded onto housing cup edge 4. To this end, adapter 6 has a holding section 7 which is formed to engage around housing cup edge 4 of housing cup 27 on a longitudinal portion 30. Longitudinal portion 30 extends along longitudinal axis 18.

Housing cup edge 4 has, on longitudinal portion 30, recesses, undercuts or projections generated by means of laser beams, in particular protruding melt beads.

Recesses 12 are formed on housing cup edge 4 on a surface of housing cup edge 4 which points radially inward. Recesses 13 are formed on an opposite surface which points outward. Recesses 14 are formed on an end side of housing cup edge 4. Recesses 12, 13 and 14 are generated, for example, by means of laser beams. The recesses jointly form a recess pattern which forms, for example, a whirl pattern in the plane of housing cup edge 4. A plastic material which forms adapter 6 has—in particular in the region of holding portion 7—penetrated into the recesses and has filled these during generation, for example molding on, of adapter 6. Adapter 6 is thus connected to housing cup edge 4 in a fixedly toothed manner. The plastic material of adapter 6 thus engages into the recesses.

In addition to the recesses, melt beads can be arranged adjacent thereto by the laser beams, which melt beads can be enclosed by the plastic material and additionally fix adapter 6 on the melt beads. The recesses can be formed on an inner side, on an end side or on an outer side or a combination of the sides on housing cup edge 4.

Adapter 6, in this exemplary embodiment an adapter ring, has a connection portion 8 formed on holding portion 7 and which is formed in this exemplary embodiment to be annular, in particular hollow-cylindrical. Connection section 8 forms the above-mentioned adapter edge.

As already mentioned, in another embodiment, the adapter can be formed to be non-rotationally symmetrical, and, to this end, for example, have a holding portion for engaging around housing cup edge 4 which forms a closed curve in accordance with the housing edge. The curve can have round portions and/or square portions.

Connection portion 8 extends in the direction of longitudinal axis 18 and is formed to be welded to housing part 9 by means of laser beams 20. A laser 19 is also represented which is formed to generate laser beams 20. For this purpose, connection portion 8 of adapter 6 is formed to be translucent for the laser beams so that laser beams 20 can penetrate through adapter 6 at least in the region of connection portion 8 without laser beams 20 being substantially absorbed. Laser beams 20 can, after penetrating through connection portion 8, strike the edge of housing cover 9 and fuse housing part 9 there so that housing cover 9 and connection portion 8 of adapter 6 can be fused to one another.

Housing 2 can thus be protected from the penetration of moisture or oil and be tightly closed off for this purpose.

In one variant, connection portion 8 and holding portion 7 are formed from different plastics, preferably thermoplastics. For example, connection portion 8 is formed from a plastic which is translucent for laser beams 20, and the connection portion is formed from an in particular particle-filled or fiber-reinforced plastic, in particular a plastic reinforced by means of glass fibers or carbon fibers, which plastic has a similar thermal coefficient of expansion to the metal of housing 2.

For this purpose, adapter 6 can be generated, for example, by means of multi-component injection molding, in the case of which the components are connected to one another in particular in a firmly bonded manner.

FIG. 2 shows—schematically—housing edge 4 already represented in FIG. 1, wherein recesses generated by means of laser beam 40 are represented in detail. A recess 31 extends orthogonally with respect to a surface of housing cup edge 4 pointing outward so that laser beam 40 can strike the surface of housing cup edge 4 orthogonally during generation of the recess pattern. A recess 32 generated on a surface which points inward runs transversely with respect to longitudinal axis 18. In one variant, a clearance 32′ runs obliquely with respect to the surface of housing cup edge 4 which points inward. As a result of this, adapter 6, in particular holding portion 7, can be connected to housing cup edge 4 in a positive-locking manner by the undercut generated in this manner.

At the rear side of housing cup edge 4, on which depressions 14 are formed in the example of FIG. 1, in FIG. 3 by way of example a depression 33 is formed which is formed orthogonally with respect to the rear side surface, and thus parallel to longitudinal axis 18, by means of laser beam 40. In one variant, the recess can be generated obliquely with respect to the surface of the rear side so that an undercut is formed, and the plastic material can flow into the recess during the formation of adapter 6. The undercut can be formed additionally to or independently of the laser beam obliquely striking the surface by a melt bead which projects beyond the recess or projects into the recess. As a result of the toothing formed in this manner, adapter 6 is connected fixedly to housing 4 in a positive-locking manner.

1. A housing (2) for an electrical device (1), the housing (2) enclosing a cavity (3) and the housing (2) comprising a housing cup (27) and a housing part (9) configured to be connected to the housing cup (27) and to close off the housing,
characterized in that the housing cup (27) has an opening (10) and the housing cup (27) at least in a region of a housing cup edge (4) formed circumferentially around the opening (10) is formed from metal, and the housing part (9) is formed from plastic, and the housing (2) comprises an adapter (6) for connection of the housing cup (27) to the housing part (9), wherein the adapter (6) is molded or fused onto a longitudinal portion (30) of the housing cup edge (4) and the adapter (6) has, at an end opposite the housing cup (27), an adapter edge (8) surrounding an adapter opening (11), which adapter edge (8) is configured to be glued or welded to the housing part (9).

2. The housing (2) as claimed in claim 1, characterized in that the housing (2) is cylindrical.

3. The housing (2) as claimed in claim 1, characterized in that the opening (11) of the adapter (6) is round toward the housing part (9).

4. The housing (2) as claimed in claim 1, characterized in that the longitudinal portion of the housing cup edge (4) has recesses (12, 13, 14, 31, 32, 33) and/or undercuts generated by laser beams (40), into which recesses and/or undercuts the adapter material has flowed and in which the adapter thus engages in a positive-locking manner.

5. The housing (2) as claimed in claim 1, characterized in that the housing cup edge (4) has a curve spanning the opening (10) toward the adapter (6), which curve has at least one rounding and/or at least one corner.

6. The housing (2) as claimed in claim 1, characterized in that the adapter (6) is connected in a region of an adapter edge (8) to the housing part (9) by laser welding.

7. The housing (2) as claimed in claim 1, characterized in that the adapter (6) is formed from different plastics, wherein the adapter edge (8) is formed from a plastic formed for laser radiation welding and a holding portion (7) of the adapter (6) connected to the housing cup edge (4) is formed from a fiber-reinforced plastic.

8. A method for connecting a housing part to a housing cup (27), the method comprising
using laser beams (20) to generate recesses or additionally undercuts (12, 13, 14, 31, 32, 33) in a housing wall of the housing cup (27), and
molding a plastic adapter (6) onto the housing cup (27), wherein the plastic of the adapter (6) penetrates into the recesses (12, 13, 14, 26, 27, 28) and thus fixedly connects the adapter (6) to the housing cup (27), and wherein the adapter (6) has an adapter edge (8), and
connecting the adapter (6) to the housing part (9) at the adapter edge (8), so that the housing cup (27) is thus closed off.

9. The method as claimed in claim 8 wherein a whirl pattern is generated by the laser beams (40) in the surface of the housing wall.

10. The method as claimed in claim 8, wherein the housing part (9) and the adapter edge (4) of the adapter (6) are welded to one another by laser beams (20).

11. The method as claimed in claim 10, wherein a projection region (34) is melted on the housing part (9) by the laser beams (20) so that a compressive tension generated by the projection region (34) can be reduced.

12. The method as claimed in claim 8, wherein the housing part is a housing cover.

13. The housing (2) as claimed in claim 1, characterized in that the housing cup (27) is cylindrical.

14. The housing (2) as claimed in claim 1, characterized in that the adapter (6) is connected in a region of an adapter edge (8) to the housing part (9) by laser radiation welding.

15. A housing (2) for an electrical machine or electric motor, the housing (2) enclosing a cavity (3) and the housing (2) comprising a housing cup (27) and a housing part (9) configured to be fixedly connected to the housing cup (27) and to close off the housing,
characterized in that the housing cup (27) has an opening (10) and the housing cup (27) at least in a region of a housing cup edge (4) formed circumferentially around the opening (10) is formed from aluminum, and the housing part (9) is formed from plastic, and the housing (2) comprises a tubular adapter (6) for connection of the housing cup (27) to the housing part (9), wherein the adapter (6) is molded or fused onto a longitudinal portion (30) of the housing cup edge (4) and the adapter (6) has, at an end opposite the housing cup (27), an adapter edge (8) surrounding an adapter opening (11), which adapter edge (8) is configured to be tightly glued or welded to the housing part (9).

16. The housing (2) as claimed in claim 15, characterized in that the housing cup (27) is cylindrical.

17. The housing (2) as claimed in claim 15, characterized in that the adapter (6) is connected in a region of an adapter edge (8) to the housing part (9) by laser radiation welding.
